(19) United States
(12) Patent Application Publication
(10) Pub. No.: US 2019/0194795 A1
(43) Pub. Date: Jun. 27, 2019

(54) SLIDING ELEMENT WITH MAX PHASE COATING

(71) Applicant: FEDERAL-MOGUL BURSCHEID GMBH, BURSCHEID (DE)

(72) Inventor: THOMAS BASTUCK, DUSSELDORF (DE)

(21) Appl. No.: 16/329,424

(22) PCT Filed: Aug. 28, 2017
(86) PCT No.: PCT/EP2017/071526

§ 371 Date: Feb. 28, 2019

(30) Foreign Application Priority Data
Aug. 31, 2016 (DE) 10 2016 216 428.7

(51) Int. Cl. C23C 14/02; C23C 14/35; C23C 14/06; C23C 14/58; F16J 9/26

(52) U.S. Cl. CPC C23C 14/025; C23C 14/351; F16J 9/26; C23C 14/0641; C23C 14/588; C23C 14/0635

(57) ABSTRACT

The invention relates to a sliding element, in particular a piston ring, to a method for producing same, and to the use of the sliding element in a tribological system. The sliding element has a coating which has at least one adhesive layer and a MAX phase layer from the inside towards the outside. The MAX phase layer has the composition Mₙ₊₁AXₙ (n=1, 2, 3), wherein M represents an element from the group Sc, Ti, V, Cr, Zr, Nb, Mo, Hf, and Ta, A represents an element from the group Al, Si, P, S, Ga, Ge, As, Cd, In, Sn, Tl, and Pb, and X represents the elements C or N.

### FIELD OF THE INVENTION

The present invention relates to a sliding element with a MAX phase coating. A sliding element of the invention is characterised by advantageous tribological properties.

### PRIOR ART

To date, coatings with high resistance to abrasive wear are used in engines in order to extend the life of sliding elements such as piston rings. Metallic, ceramic or DLC layer systems are state of the art and are already widely used in industrial applications. The metallic, ceramic or DLC properties are noticeable depending on the layer system. However strong the various layer systems might be, they are also limited in terms of adjustability and therefore usefulness of the relevant properties needed to obtain the pursued broad characteristic diagram in a tribological stress complex such as a combustion engine. For desirably low coefficients of friction, carbon-containing metal layer systems or DLC layer systems are especially used. DLC coatings ensure a majority of the desired properties, such as for example lower friction, higher resistance to abrasive wear and maximal abrasion resistance in case of deficient lubrication. However, they show limitations, such as for example oxidation stability at high temperatures, mechanical workability in comparison to metals, or poor synergistic effects with the additives used in engine oils.

So-called MAX phases are further known in the art. Given their high thermal stability and electrical conductivity, these are also used as a coating for components in relevant fields of application. MAX phases are a material family of nanolayered composites with the composition M₍ₙ₊₁₎AX₍ₙ₎, wherein n=1 to 3. M represents a transition metal, A is an element from group A, and X represents nitrogen and/or carbon. The hexagonal structure of the MAX phases consists of octahedra nested with layers of elements from the A group. The transition metals comprise in this context Sc, Ti, V, Cr, Zr, Nb, Mo, Hf and Ta, and the elements from group A comprise Al, Si, P, 5, Ga, Ge, As, Cd, In, Sn, Tl and Pb.

The crystal lattices of the Max phases form in unit cells (211), (312) and (413). Possible MAX phases are:

Unit cell type 211:

Ti₂CdC, Sc₂InC, Ti₂AlC, Ti₂GaC, Ti₂InC, Ti₂TlC, V₂AlC, V₂GaC, Cr₂GaC Ti₂AlN, Ti₂GaN, Ti₂InN, V₂GaN, Cr₂GaN, Ti₂GeC, Ti₂SnC, Ti₂PbC, V₂GeC, Cr₂AlC, Cr₂GeC, V₂PC, V₂AsC, Ti₂SC, Zr₂InC, Zr₂TlC, Nb₂AlC, Nb₂GaC, Nb₂InC, Mo₂GaC, Zr₂InN, Zr₂TlN, Zr₂SnC, Zr₂PbC, Nb₂SnC, Nb₂PC, Nb₂AsC, Zr₂SC, Nb₂SC, Hf₂InC, Hf₂TlC, Ta₂AlC, Ta₂GaC, Hf₂SnC, Hf₂PbC, Hf₂SnN, Hf₂SC

Unit cell type 312:

Ti₃AlC₂, V₃AlC₂, Ti₃SiC₂, Ti₃GeC₂, Ti₃SnC₂, Ta₃AlC₂

Unit cell type 413:

Ti₄AlN₃, Ti₄GaC₃, Ti₄SiC₃, Ti₄GeC₃, Nb₄AlC₃, Ta₄AlC₃

Given that the M-X bonds have a strong covalent nature, M₍ₙ₊₁₎AX₍ₙ₎ phases typically display ceramic properties. On the other hand, the M-A bonds are comparatively weak, with the consequence that M₍ₙ₊₁₎AX₍ₙ₎ phases also display metallic properties. The material deforms through buckling under the application of force, which results in a high ductility and rnachinability (see also F. Adibi et al. J. Appl. Phys. 69 (1991) 6437 and Barsoum, Michel W., and Tamer El-Raghy. “The MAX Phases: Unique New Carbide and Nitride Materials Ternary ceramics turn out to be surprisingly soft and machinable, yet also heat-tolerant, strong and lightweight,” Am. Scientist 89.4 (2001): 334-343 as well as M. W. Barsaum et al, Phys. Rev. 62 (2000) 10194).

Components with MAX phase coatings are generally known from the prior art.

EP 1 685 626 B1 describes an element for making an electric contact to a contact member for enabling an electric current to flow between said eluent and said contact member. A contact surface of said element is coated with a contact layer having composition MAXn where n=1, 2, 3 or more, M is a transition metal or a combination of transition metals, A represents an element from group A or a combination of elements from group A, and X represents nitrogen and/or carbon.

EP 2 405 029 A1 relates to a method for producing an adhesion-resistant and scratch-resistant protective layer on a metallic workpiece, wherein the protective layer shows a low blast wear, and the method comprises the coating of the workpiece with a M₍ₙ₊₁₎AX₍ₙ₎ phase where M=Ti, Cr, V, Nb or Mo; A Ga, Al, Ge or Si; X=C or N; and where n=1, 2 or 3.

U.S. Pat. No. 8,192,850 B1 describes a combustion turbine part comprising a substrate and an adhesive layer provided on the substrate, wherein the adhesive layer may comprise M₍ₙ₊₁₎AX₍ₙ₎ phases (n=1, 2, 3), and wherein M is selected from groups IIIB, IVB, VB, VIB and VII of the periodic table of elements and combinations thereof, A is selected from groups IIIA, WA, VA and VIA of the periodic table of elements and combinations thereof, and X comprises at least carbon or nitrogen.

WO 2006/057618 A2 relates to a coated product consisting of a metallic substrate and a composite coating including the MAX material, wherein the M₍ₙ₊₁₎AX₍ₙ₎ phase comprises at least one transition metal from the group M=Ti, Sc, V, Cr, Zr, Nb, Ta, at least one element from the group A=Si, Al, Ge and/or Sn, and at least one of the elements C and/or N, wherein n=0.8-3.2 and z=0.8-1.2.

EP 2 740 819 A1 discloses a layer system for a compressor blade comprising an aluminium-rich MAX phase as a coating, or in which the coating consists of an aluminium-rich MAX phase.

Finally, Gupta et al. describe the tribological behaviour of selected MAX phases against nickel-based superalloys (Gupta, Surojit, et al. “Ambient and 550 C tribological behavior of select MAX phases against Ni-based superalloys.” Wear 264.3 (2008): 270-278).

### SUMMARY OF THE INVENTION

The invention aims at providing a sliding element, preferably a piston ring, a method for producing the same and the use of said sliding element in a tribological system, wherein the sliding element displays a long lifetime, advantageous tribological properties and good workability.

This is achieved with the sliding element described in claim 1, the method for producing the sliding element according to claim 10 and the use of the sliding element according to claim 13.

The inventors were able to show that the coating of the sliding element according to claim 1, in particular the MAX phase layer, represents a combination of typical property profiles inherent to conventional layer systems which is advantageous for tribological applications.

In this context, the atomic bond structure of the so-called MAX phase layer promotes synergistic use of ceramic as well as metallic properties, and the limitations of the respective layer systems can be remedied. Moreover, given that the MAX phase layer contains by definition carbon or nitrogen, it generates low friction values and shows good dry-running properties in the event of deficient lubrication.

The ceramic properties of the MAX phase layer ensure a high thermal stability, good oxidation resistance at high temperatures, as well as improved corrosion resistance. The good thermal conductivity and resistance against thermal shock stresses are by contrast due to the metallic properties of the MAX phase layer. Furthermore, the resulting coating lends itself very well to machining by stock removal and shows an exceptionally high tolerance to tribological stress.

Moreover, the inventors have surprisingly discovered that the use of an adhesive layer extends significantly the life of the whole coating system. The adhesive layer fulfils the functional purpose of ensuring adhesion between the sliding element substrate and the coating. More particularly, the adhesive layer compensates for potential tensions due to differing thermal expansion coefficients in the sliding element substrate and coating. This compensation of tensions improves the adhesion and allows the sliding element to compensate, in use, for thermal stress differences and tension states which these differences generate in the material complex consisting of the sliding element substrate and the coating. This means that a mere application of the adhesive layer also leads to extending the excellent tribological properties of the MAX phase layer in the long term.

Preferred developments of the sliding element according to the invention are described in the further claims.

Preferably, the adhesive layer comprises chromium, chromium nitride, titanium and/or tungsten. More preferably, the adhesive layer consists of said materials. It has been shown that selecting such materials significantly improves adhesion of the coating.

Advantageously, the thickness of the adhesive layer is 0.1 to 3.0 μm. Thinner layers do not lead to improved adhesion, whereas thicker layers are undesirable from an economical point of view.

Further, according to the invention, the coating is to be applied onto a sliding element substrate, wherein the sliding element substrate consists of cast iron or steel. Particularly preferred materials are the following: unalloyed, untempered cast iron with lamellar graphite, alloyed grey cast iron with carbides (heat-treated or not heat-treated), tempered spheroidal cast iron, untempered vermicular graphite cast iron, cast steel with at least 10% by weight chromium (nitrided or non-nitrided), chromium steel with at least 10% by weight chromium (nitrified or non-nitrided) and chromium-silicon-carbon steel. Said materials are particularly suited to ensure the resistance of the sliding element.

Preferably, the coating has an average roughness depth R_{z}<7 μm, preferably R_{z}<4 μm, a reduced peak depth Rₚₖ<0.4 μm, preferably Rₚₖ<0.2 μm, and/or a core roughness depth Rₖ<1 μm, preferably Rₖ<0.6 μm. Such a coating improves the frictional properties of the sliding element.

Advantageously, in the composition Mₙ₊₁AXₙ of the MAX phase layer, element M represents either Ti or Cr, element A represents either Al or Si, and n=1 or 2. The MAX phase layers with said chemical compositions are well suited to tribological applications and are characterised by easily-available chemical components.

It is particularly preferred to use the MAX phase layers of the invention showing following layer types:
Cr₂AlC: type 211; proportion of Cr: 48-52 at. %; proportion of Al: 24-26 at. %; proportion of C: 24-26 at. %
Cr₂AlN: type 211; proportion of Cr: 48-52 at. %; proportion of Al: 24-26 at. %; proportion of N: 24-26 at. %
Ti₂AlC: type 211; proportion of Ti: 48-52 at. %; proportion of Al: 24-26 at. %; proportion of C: 24-26 at. %
Ti₂AlN: type 211; proportion of Ti: 48-52 at. %; proportion of Al: 24-26 at. %; proportion of N: 24-26 at. %
Ti₃SiC₂: type 312; proportion of Ti: 48 -52 at. %; proportion of Si: 16-18 at. %; proportion of C: 32-34 at. %,

Test series have shown that these layer types display particularly advantageous lifetimes, coupled with excellent tribological properties.

It is further preferred that the coating has a hardness of 2 to 6 GPa. On the one hand, this range ensures a minimum protection against abrasion for the sliding element, and on the other hand it avoids unnecessarily strong abrasive damage to the pairing friction part,

Advantageously, the coating further has a modulus of elasticity of 150 to 350 GPa. In fact, the resistance of the coating decreases as the modulus of elasticity decreases. In cases where the coating gets deformed with the substrate, a lower modulus of elasticity of the coating may however extend the lifetime of the layer. The above range for the modulus of elasticity therefore represents the optimal range for an application as a sliding element.

A preferred embodiment of the method according to the invention for the production of a sliding element includes the following method steps: providing a sliding element substrate, preferably consisting of cast iron or steel; coating at least a partial surface of the sliding element substrate with an adhesive layer, wherein the adhesive layer preferably contains chromium, chromium nitride, titanium and/or tungsten, and more preferably consists of chromium, chromium nitride, titanium and/or tungsten; and coating at least a part of the adhesive layer with a MAX phase layer, wherein the MAX phase layer has the composition Mₙ₊₁AXₙ (n=1, 2, 3), and wherein M represents an element from the group Sc, Ti, V, Cr, Zr, Nb, Mo, Hf and Ta, A represents an element from the group Al, Si, P, S, Ga, Ge, As, Cd, In, Sn, Tl and Pb, and X represents the elements C or N. This leads to the economically efficient production of sliding elements with improved lifetime, advantageous tribological properties and good processability.

Advantageously, in the production method, the roughness of the MAX phase layer and/or adhesive layer can be reduced following the coating process by lapping, belt and/or brush polishing. This results in sliding elements with improved frictional properties.

Further, in the invention, at least one layer of the coating is deposited by means of a PVD method, CVD method or thermal spraying, preferably by means of High Power Pulsed Magnetron Sputtering (HPPMS) or Pulse Laser Deposition (PLD). These methods lead to superior layer qualities with acceptable production times.

The use of a sliding element according to the invention is particularly preferred in a tribological system, preferably in an Otto or Diesel engine, consisting at least of said sliding element, a pairing friction part which remains in frictional contact with said sliding element, and at least one lubricant, preferably engine oil, said lubricant containing additives. The metallic properties of the MAX phase layer give rise to polar surface conditions in the coating, which are crucial for the electron exchange with additive components in the lubricants and therefore with the formation of so-called tribofilrns. As such, additional synergistic effects between coating technology and lubricant technology can be utilised in the tribological stress complex with respect to abrasive wear protection and friction reduction.

Additives such as organic friction modifiers, for example glycerol mono-oleates (GMO), inorganic friction modifiers, for example molybdenum dialkyldithiocarbamates (MoDTC), and/or polymeric friction modifiers have proved to be especially well suited. The polymeric friction modifiers differ from conventional friction modifiers in that their molecules are in the form of long polymer chains (5000-50000 Daltons [Da]). By contrast, conventional friction modifiers consist of small molecules (250-300 Daltons [Da]). The polymer structure advantageously improves the stability of the lubricant film on the running surfaces (cylinder and coating on the piston ring).

As regards the composition of the MAX phases, lower concentration variations, in particular variations from the stoichiometric sum formula of up to ±2 at. %, are also included in the scope of the invention.

### PREFERRED EMBODIMENT

A preferred embodiment consists in a sliding element in the form of a piston ring whose base material is chromium-silicon-carbon steel. The outer circumferential surface of the piston ring has the function of a substrate onto which a chromium nitride-adhesive layer is first deposited by means of a PVD method to a thickness of 1 μm. A MAX phase layer with a thickness of 1 μm with the sum formula Ti3SiC2 is then applied onto the adhesive layer by means of High Power Pulsed Magnetron Sputtering (HPPMS), with the actual proportions of components Ti: 48-52 at. %, Si: 16-18 at. % and C: 32-34 at. %. The average roughness depth of the coating is finally adjusted by belt polishing to a value R_{z}<4 μm. A sliding element with the above-described coating shows more particularly an extreme robustness under thermal stress against oxidation and fracture.

1. A sliding element with a coating, which from the inside outwards, has at least the following layers:
one adhesive layer, and a MAX phase layer with the composition Mₙ₊₁AXₙ (n=1, 2, 3), wherein M represents an element from the group Sc, Ti, V, Cr, Zr, Nb, Mo, Hf and Ta, A represents an element from the group Al, Si, P, S, Ga, Ge, As, Cd, In, Sn, Ti and Pb, and X represents the elements C or N.

2. The sliding element according to claim 1, wherein the adhesive layer contains chromium, chromium nitride, titanium and/or tungsten.

3. The sliding element according to claim 1, wherein the thickness of the adhesive layer is 0.1-3.0 μm.

4. The sliding element according to claim 1, wherein the coating is applied onto a sliding element substrate and the sliding element substrate consists of cast iron or steel, and consists of one of the following materials:
unalloyed, untempered cast iron with lamellar graphite
alloyed, heat-treated or not heat-treated grey cast iron with carbides
tempered spheroidal cast iron
untempered vermicular graphite cast iron
cast steel with at least 10% by weight chromium, nitrided or non-nitrided
chromium steel with at least 10% by weight chromium, nitrided or non-nitrided
chromium-silicon-carbon steel.

5. The sliding element according to claim 1, wherein the coating has an average roughness depth R_{z}<7 μm, a reduced peak depth Rₚₖ<0.4 μm, and/or a core roughness depth Rₖ<1 μm.

6. The sliding element according to claim 1, wherein in the MAX phase layer with the composition Mₙ₊₁AXₙ, element M represents either Ti or Cr, element A represents either Al or Si and n=1 or 2.

7. The sliding element according to claim 6; wherein the MAX phase layer is selected from one of the following layer types:
Cr₂AlC: type 211; proportion of Cr: 48-52 at. %; proportion of Al: 24-26 at. %; proportion of C: 24-26 at. %
Cr₂AlN: type 211; proportion of Cr: 48-52 at. %; proportion of Al: 24-26 at. %; proportion of N: 24-26 at. %
Ti₂AlC: type 211; proportion of Ti: 48-52 at. %; proportion of Al: 24 -26 at. %; proportion of C: 24-26 at. %
T₁₂AlN: type 211; proportion of Ti: 48-52 at. %; proportion of Al: 24-26 at. %; proportion of N: 24-26 at. %
Ti₃SiC₂: type 312; proportion of Ti: 48 -52 at. %; proportion of Si: 16-18 at. %; proportion of C: 32-34 at. %,

8. The sliding element according to claim 1, wherein the coating has a hardness of 2 to 6 GPa.

9. The sliding element according to claim 1, wherein the coating has a modulus of elasticity of 150 to 350 GPa.

10. A method for producing a sliding element according to claim 1, comprising the following steps:
providing a sliding element substrate,
coating at least a partial surface of the sliding element substrate with an adhesive layer, wherein the adhesive layer contains chromium, chromium nitride, titanium and/or tungsten, and
coating at least a part of the adhesive layer with a MAX phase layer, wherein the MAX phase layer has the composition Mₙ₊₁AXₙ (n=1, 2, 3), and wherein M represents an element from the group Sc, Ti, V, Cr, Zr, Nb, Mo, Hf and Ta, A represents an element from the group Al, Si, P, S, Ga, Ge, As, Cd, In, Sn, Tl and Pb, and X represents the elements C or N.

11. The method according to claim 10, wherein the roughness of the MAX phase layer and/or adhesive layer can be reduced after the coating process by lapping, belt and/or brush polishing.

12. The method according to claim 10, characterised in that at least one layer of the coating is deposited by means of a PVD method, CVD method or thermal spraying.

13. A sliding element according to claim 1 in a tribological system, including said sliding element and, a pairing friction part which remains in frictional contact with said sliding element, and at least one lubricant, wherein the lubricant contains additives.

14. The element in a tribological system according to claim 13, wherein the additives comprise organic friction modifiers, inorganic friction modifiers and/or polymeric friction modifiers.

15. The sliding element according to claim 1, wherein the sliding element is a piston ring.

16. The sliding element according to claim 1, wherein the adhesive layer consists of chromium, chromium nitride, titanium and/or tungsten,

17. The sliding element of claim 5, wherein R_{z}<4 μm, Rₚₖ<0.2 μm and Rₖ<0.6 μm.

18. The method according to claim 10, wherein the substrate is cast iron or steel.

19. The method according to claim 10, wherein the adhesive layer consists of chromium, chromium nitride, titanium and/or tungsten.

20. The method according to claim 12 wherein the coating deposition is carried out by means of High Power Pulsed Magnetron Sputtering (HPPMS) or Pulsed Laser Deposition (PLD).

21. The sliding element according to claim 13, wherein the tribological system is a Diesel or Otto engine.

22. The sliding element according to claim 13, wherein the lubricant is engine oil.
